(19) United States
(12) Patent Application Publication
(10) Pub. No.: US 2004/0009304 A1
(43) Pub. Date: Jan. 15, 2004

(54) Process and tool with energy source for fabrication of organic electronic devices

(75) Inventors: Karl Pichler, Santa Clara, CA (US); Matthias Stoessel, Mannheim (DE)

Correspondence Address: Elsa Keller, Intellectual Property Department, Siemens Corporation, 186 Wood Avenue South, Iselin, NJ, 08830, US

(73) Assignee: Osram Opto Semiconductors GmbH & Co. OGH

(21) Appl. No.: 10/191,911

(22) Filed: Jul. 9, 2002

(51) Int. Cl. H01L 21/31; H01L 21/469; B05D 3/00

(52) U.S. Cl. 427/551; 438/99; 438/782

(57) ABSTRACT

A system and method is presented for deposing a liquid on a substrate. The print head of an ink-jet printer emits a liquid containing ink and at least one other component. An energy beam, such as a laser, with sufficient intensity substantially causes at least a partial modification, such as evaporation, of a component of the liquid, thereby altering the drying profile. The ink deposed on the substrate may be used to create devices such as organic transistors and OLEDs.

### BACKGROUND OF THE INVENTION

1. Field of the Invention

The present invention relates to an ink-jet printing process and tool. More particularly, the present invention relates to an ink-jet process and tool for use in the deposition of ink-jet materials, such as those used in organic electronic devices such as organic transistors and integrated circuits, as well as for organic light-emitting devices (OLEDs).

2. Description of Related Art

One conventional type of printer forms characters and images on a medium or substrate, such as paper, by expelling droplets of ink, often comprising organic material, in a controlled fashion so that the droplets land on the medium in a pattern. Such a printer can be conceptualized as a mechanism for moving and placing the medium in a position such that ink droplets can be placed on the medium, a printing cartridge which controls the flow of ink and expels droplets of ink to the medium, and appropriate control hardware and software. A conventional print cartridge for an inkjet type printer comprises an ink containment device and a fingernail-sized apparatus, commonly known as a print head, which heats and expels ink droplets in a controlled fashion. The print cartridge may contain a storage vessel for ink, or the storage vessel may be separate from the print head. Other conventional inkjet type printers use piezo elements that can vary the ink chamber volume through use of the piezo-electric effect to expel ink droplets in a controlled fashion. Helpful background material may be found in various publications, such as, by way of example only, U.S. Pat. No. 5,764,247, which is incorporated by reference to the extent not inconsistent with the present invention.

Applications of inkjet printers have moved beyond the conventional creation of characters and images for viewing by people to the creation of circuits and displays, for example the organic display panels. Helpful background material may be found in various publications, such as, by way of example only, European Patent Applications EP 0 732 868 A1 and EP 0 880 303 A1. These publications are incorporated by reference to the extent not inconsistent with the present invention.

Inkjet printing is being used or developed as a tool to deposit organic materials in a patterned manner onto substrate to create organic, or partially organic, electronic devices such as, by example only, transistors (such as organic field-effect transistors) and integrated circuits, conductive via holes or traces, organic light-emitting devices (OLEDs). Helpful background material may be found in various publications, such as, by way of example only, H. Sirringhaus et al., Science 290, 2123 (2000), E. I. Haskal et al., SID '02 Digest, 776 (2002), and S. Burns et al., SID 02 Digest, Society for Information Display, Boston, May 2002, paper 43.1, pp. 1193-1195 (2002). These publications are incorporated by reference to the extent not inconsistent with the present invention.

Typically, the organic material is a solute that is dissolved at low concentration in a solvent (which may or may not be organic itself) to create a solution, such as, by example only, poly (3,4-ethylenedioxythiophene)-polystyrenesulfonate (PEDOT/PSS, available from Bayer AG, having an office in Pittsburgh, Pa.) in water, dispersions, UV-curable or thermally curable glues, adhesives or epoxies, or emissive polymers or molecules for OLEDs in organic solvents or solvent mixes. Such a solution (which is also often referred to as ink) is then printed onto suitable substrate using ink-jet printing. Some types of substrates used, by way of example only, are glass substrates, plastic substrates (such as polyethylene terephthalate, polyethylene naphthalate, polymide, polycarbonate), metal foils, ceramic substrates, laminated glass, and thin flexible glass. Some applications for substrates, by way of example only, are substrates for organic thin film transistors (TFTs), hybrid organic/inorganic TFTs, alphanumeric or passive-matrix or active-matrix OLEDs or combined TFT/OLED devices.

In some applications, more than one inkjet print nozzle will be designed into a printer. Usually this multiple nozzle assembly is created to accommodate multiple solutions. The clarity and quality of the resultant printed patterns is affected by, among other factors, the quality of the solution(s) and the accuracy of the placement of the solution droplets on the substrate. Printers that use multiple print cartridges, or alternatively an array of nozzles, to cooperatively form a single image usually require mechanical or electronic adjustment so that droplets printed by one nozzle alight at precise locations on the receiving substrate relative to those printed by another nozzle in the printer. Alternatively, continuous-stream ink-jet printing with electrostatic deflection or micro-dosing may be employed. Helpful background material may be found in various publications, such as, by way of example only, S. F. Pond: “Inkjet Technology”, Torrey Pines Research (2000), which is incorporated by reference to the extent not inconsistent with the present invention.

A challenge with the techniques described above for creating printed film is that many different requirements must be met while maintaining the desired uniformity and quality of the resulting components, such as printed areas, printed segments, printed lines, printed pixels, printed traces, and printed via-holes, by way of example only. Some of the “printing factors” that are often taken into consideration are as follows.

Only a limited choice of solutes, such as organic conductive materials, organic electro-luminescent materials, polymers, molecules, and oligomers, by way of example only, is available to make such organic electronic devices and displays with acceptable performance characteristics.

Those solutes that are used must be brought into a solution that is amenable to ink-jet printing (allowing continuous stream printing and drop-on demand) and/or micro-dispensing; thus, the types of solvents that may be used with a given solute are limited. Helpful background material may be found in various publications, such as, by way of example only, Great Britain Patent No. 2 336 553 A, which is incorporated by reference to the extent not inconsistent with the present invention.

The types of solvents that may be used may be further limited by the print head (which may comprise a printing nozzle or micro-dispenser, by way of example only). The solvents used with a given print head must be compatible with that print head.

The use of additives, which may otherwise be commonly used for ink-jet printing to improve the solutions and printing process, is limited because it may interfere with the quality of the print.

The solution leaving the print head must be stable for proper placement on the substrate.

The solution must be compatible with the substrate on which it is to be printed. Often compatibility between the solution and layers that may exist under a surface substrate layer is also a consideration.

The solution often needs to be contained in walls (such as troughs or banks, by way of example only) in or on the substrate to prevent spreading. Helpful background material may be found in various publications, such as, by way of example only, European Patent Application EP 0 892 028 A2, which is incorporated by reference to the extent not inconsistent with the present invention. Preferably, the solution should wet the substrate itself but not the walls that contain the solution. This is another reason that, as mentioned above, compatibility between the substrate and solution is a factor.

For most applications, the solution should create a uniform film on the substrate which means, in most cases, that the solution must dry in a uniform manner as it is deposited. By way of example only, the uniformity of drying can affect, in the case of OLEDs, uniformity, lifetime, efficiency, and color gamut.

According to the prior art, it is impossible to create a solution that perfectly meets each of the above factors. There are trade-offs that are taken into account when solutions are developed and, depending on the application and other criteria (such as cost), a solution is typically designed with some of the above factors weighted more heavily than others. A factor having particularly difficult conditions to achieve, given all others, is to get a uniform ink film on the substrate after deposition. A reason for this difficulty is that very often solution drops show so-called “coffee stain” drying profiles. Capillary flow causes ring stains from dried liquid drops, whereby within a printed drop (or line or area) fluid-dynamic effects cause the edges of the drop (or line or area) to have a substantially higher concentration of solute than the center. This is often not acceptable for device performance. Though this effect can be mitigated by careful choice of the drying ambient (such as temperature and/or atmospheric pressure, by way of example only) and/or the choice of solvents (adjusting the boiling point, solvent strength, solvent mix, and/or surface energy, by way of example only), disadvantageously other printing factors outlined above are adversely affected substantially enough to degrade printing quality. For example, though coffee-stain types of drying effects can be reduced by using a highly viscous solvent and/or by using solute that is poorly dissolved in the solution (and therefore precipitates or “crashes out” of the solution), a highly-viscous solution or poorly dissolved solution can be very problematic for the printing or dispensing process itself (causing, by way of example only, nozzle clogging and/or inaccurate drop firing or dispensing).

Conversely, when the design of the solution takes most of the printing factors into account, to the extent that the ink drops (or streams) would create good printing process performance, the end result in the prior art is non-uniform drying that adversely affects the final print quality.

### SUMMARY OF THE INVENTION

It is therefore an object of the present invention to provide a process and tool to modify the drying process of solutions that improves the final print quality on the substrate.

It is another object of the present invention to modify the drying process of solutions by hastening the drying time of solutions utilizing an energy beam.

It is another object of the present invention to provide a heat source to evaporate at least part of the solvent in a solution subsequent to the solution leaving an ink-jet print head or nozzle.

It is yet another object of the present invention to provide a solution comprising a solvent with a low temperature boiling point to allow a heat source to evaporate at least part of the solvent subsequent to the solution leaving a print head or nozzle.

It is yet another object of the present invention to provide a method of evaporating at least part of the solvent in a solution subsequent to the solution leaving a print head or nozzle.

It is yet another object of the present invention to match the properties of a solvent and the wavelength of a heat source with each other to facilitate the evaporation of at least part of the solvent subsequent to a solution containing the solvent leaving a print head or nozzle without substantially adversely affecting active component(s) of the solution.

It is yet another object of the present invention to match the properties of an ink and the wavelength of an energy source with each other to facilitate modification of the ink to improve the final print quality.

A laser beam or other energy source is used to increase the temperature of a liquid drop or stream, such as a solution drop or stream, after it has left the print head or nozzle. The energy can cause at least one of the following: at least a portion of the solvent evaporates thereby increasing the viscosity of the solution; the solubility of the solute in the solution is reduced; the organic material or a portion thereof in the solution precipitates. Use of energy in this manner permits the use of solvents and/or additives that would, absent the use of the energy source, substantially adversely affect the drying behavior of the liquid. Thus, advantageously, the present invention allows the use solvents and/or additives in liquids that goes against (or in such quantities that goes against) teachings in the prior art.

### BRIEF DESCRIPTION OF THE DRAWINGS

FIG. 1 is a diagram showing various placements of an energy beam relative to a print head, liquid droplet, and substrate with a confinement wall.

FIG. 2 is a diagram showing various placements of an energy beam relative to a multiple-nozzle print head, liquid droplet, and substrate without a confinement wall.

FIG. 3 is a diagram showing various placements of an energy beam relative to a print head, continuous jet or continuous stream of liquid, and substrate.

### DETAILED DESCRIPTION

In a preferred embodiment, the invention is described in an implementation for the application of circuit and/or display components on substrates. The invention may be, in other preferred embodiments, implemented for other purposes, such as the application of ink on paper or other medium for the purpose of creating characters and/or images for viewing by way of example only.

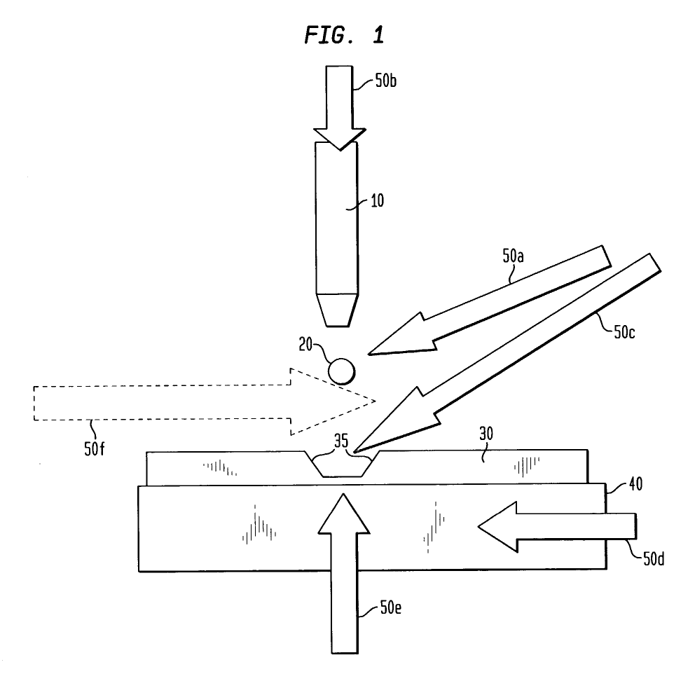

With reference to FIG. 1, a preferred embodiment of the invention is shown. Print head 10, is for the purpose of this specification is any device that emits a liquid in a controlled fashion, using, by way of example only, a printing nozzle, printing plate, or dispensing nozzle. In a preferred embodiment print head 10 has multiple nozzles, though in an alternative preferred embodiment print head 10 has a single nozzle. Examples of print heads may be found in Ink Jet Technology by Stephen F. Pond, Ph.D., Torrey Pines Research, 2000.

Print head 10 emits liquid 20 toward substrate 30. In a preferred embodiment this is accomplished by way of drop-on-demand ink-jet printing (such as bubble-jet, piezo-electric, electrostatic or other), though in alternative preferred embodiments other ink-jet printing technology may be used, such as continuous stream ink-jet printing or micro-dispensing, by way of example only. Examples of printing technologies may be found in various publications, such as, by way of example only, in Ink Jet Technology by Stephen F. Pond, Ph.D., Torrey Pines Research, 2000, which is incorporated by reference to the extent not inconsistent with the present invention.

In a preferred embodiment, liquid 20 is a solution droplet and comprises a solvent and solute for the creation of electronic devices, such as, by way of example only, OLED devices, organic transistors, diodes, integrated circuits, circuit lanes, or via holes. Examples may be found in T. Kawase et al., SID '01 Digest, p. 40ff (2001), which is incorporated by reference to the extent not inconsistent with the present invention. In preferred embodiments, the solute may comprise organic materials such as PEDOT/PSS, Pani, other charge-transporting materials, light-emissive materials such as those based on PPV-type polymers, fluorene-based polymers, monomers, oligomers, and materials based on a spiro-compound, by way of example only. In other preferred embodiments, co-polymers, co-monomers, and co-oligomers are used. In preferred embodiments the solvent may comprise water, a polar solvent, organic solvent, a mix of solvents, mixes of solvents with different solvent strengths mixes of solvents with different boiling points, mixes of solvents with different surface energies, and mixes of solvents with different absorption spectra, by way of example only.

In an alternative preferred embodiment, the ink itself is a liquid and does not need an additional solvent. By way of example only, the ink may be UV-curable with low molecular weight or otherwise cross-linkable compound. In another alternative preferred embodiment, an energy-absorbing special additive (which may have properties to make it more sensitive to certain wavelengths) is added to liquid 20 to modify the drying process of liquid 20 when energy is applied.

In a preferred embodiment, the solvent has a lower boiling point than the sublimation point of the solute in solution 20. Advantageously, the application of a heat source to solution 20 assists the evaporation of the solvent. However, as described in greater detail below, it is possible to utilize a solution wherein the solvent has a higher boiling point than the sublimation point of the solute, if the heat source can selectively have a greater effect on the evaporation of the solvent than on the sublimation of the solute.

An example of a solution that may be used in conjunction with the present invention is a fluorene-based copolymer (that serves as the emitter-polymer in an OLED) dissolved in an 80% xylene/20% TMB (1,2,4 tri-methyl benzene) solvent mix.

Substrate 30 can be flexible (composed of material such as plastic, metal foil, or thin/ultra-thin glass, by way of example only), semi-flexible, or rigid (composed of silicon wafers or of glass with or without pre-patterned structures such as active matrices or passive matrices, by way of example only). The selection of substrate 30 depends on the liquid 20 being applied (by way of example only, an OLED substrate may be used with a fluorene-based copolymer solute). In a preferred embodiment, substrate 30 has confinement walls 35 (which are, by way of example only, patterned polyimide) to hold solution 20. One or more layers 40 may exist under substrate 30. The composition of layers 40 depends on the type of substrate 30 used and may also depend on the composition of liquid 20 if there is interaction between at least the top layer 40 and liquid 20.

FIG. 1 shows the possible placement of energy beam 50. In a preferred embodiment, there is only one energy beam 50, though multiple energy beam 50 may be used in alternative preferred embodiments. Energy beam 50 modifies liquid 20 by way of heating, in a preferred embodiment. Energy beam 50a sends energy to liquid 20 after liquid 20 is emitted from print head 10 but before liquid 20 strikes substrate 30. Other preferred embodiments are shown, wherein: energy beam 50b sends energy through print head 10; energy beam 50c imparts energy from above substrate 30 and imparts energy to substrate 30; energy beam 50d sends energy through layer 40 and/or through substrate 30 from the side (if substrate 30 is not transparent to energy beam 50d but has holes, then in a preferred embodiment only liquid 20 that is disposed within the holes receive, through layer 40, a substantial amount of energy); energy beam 50e sends energy through layer 40 from below; energy beam 50f creates an energy curtain substantially parallel to substrate 30 and imparts energy to liquid 20 (before and/or after liquid 20 strikes substrate 30, depending on how close the energy curtain is to substrate 30). It is also possible to have multiple energy paths by having combinations of the above. By way of example only, energy beam 50a might be used to heat liquid 20 before it strikes substrate 30 while energy beam 50c might be used to heat substrate 30 (before, during, and/or after liquid 20 strikes substrate 30). When multiple energy beams 50 are used, they can have different properties, such as different wavelength or different intensity, by way of example only.

In a preferred embodiment, energy beam 50 is a laser beam that is produced by a laser (not shown) of suitable wavelength and intensity that substantially aids in the evaporation of one or more solvents in solution 20. In a preferred embodiment energy beam 50 has an asymmetric broad profile, though in alternative preferred embodiments energy beam 50 may have a different profile, such as an ellipse, rectangle, line, or donut-shaped, by way of example only. Energy beam 50 may be continuously on or may be pulsed. If pulsed, the pulses may be synchronized with the emission of liquid 20. In a preferred embodiment, energy beam 50 directly evaporates one or more solvents of the ink, though in alternative preferred embodiments the energy is selectively absorbed by one or more of the solvents, or energy beam 50 is directed at substrate 30 and warms a portion of substrate 30 that is or soon will be in contact with solution 20.

Energy beam 50 may have a narrow cross-section or be widened (for example, an energy curtain may cover a substantial portion of the distance between print head 10 and substrate 30). On the other hand, if energy beam 50 is pulsed, it may be a narrow beam that targets liquid 20 as it travels from print head 10 to substrate 30.

Lenses and/or masks may be used to further control the properties of energy beam 50. Such devices may be used to tailor the energy beam profile to the liquid 20 and/or the desired pattern on substrate 30. By way of example only, a cylindrical lens may be used to form the energy curtain described above.

Preferably, a pulsed energy beam 50 operates in synchronization with print head 10. For example, energy beam 50 may be stationary with respect to print head 10. By way of example only, the source of energy beam 50 may be secured to print head 10, and if at least a portion of print head 10 is transparent to energy beam 50 or can function as a waveguide, energy beam 50 may go through print head 10, as shown by energy beam 50b. In an alternative preferred embodiment, energy beam 50 is stationary with respect to substrate 30 for at least a period of time.

In a preferred embodiment, if energy beam 50 is pulsed, the period of time that solution 20 receives energy is controlled by the length of the pulse. Thus, the maximum temperature reached by liquid 20 can be controlled and the pulse turned off before energy beam 50 adversely affects the properties of liquid 20.

In a preferred embodiment, the laser used as a source for energy beam 50 is an -infrared (IR) laser, which could be either tunable or fixed wavelength. Various technologies may be implemented for a laser suitable for the present invention, such as diode-laser, dye-laser, gas-based laser, or solid state laser, by way of example only. In a preferred embodiment, the wavelength and energy of the laser is tuned to a spectral range at which the solvent in solution 20 absorbs the laser energy, but the solute and substrate 30 do not substantially absorb laser energy. By way of example only, energy beam 50 has a very specific wavelength and a very narrow spectrum to ensure that only a solvent or solvents in solution 20 absorb a substantial amount of energy. In an alternative preferred embodiment, energy beam 50 is deliberately tuned to a spectral range that modifies the solute in a certain advantageous way, such as, by way of example only, causing the solute to at least partially gel, undergo a chemical reaction, aggregate, partially cross-link, or split off chemical groups.

Energy absorption may take place by way of optical absorption, vibrational absorption, and/or rotational absorption, by way of example only. In an alternative preferred embodiment, the wavelength and energy of the laser is tuned to a spectral range at which substrate 30 and/or confinement walls 35 absorbs the laser energy. Absorption of the energy may take place before, during, or after liquid 20 strikes substrate 30, or combinations thereof.

In alternative preferred embodiments, the source of energy beam 50 is a focused lamp or light emitting diode (LED) that is placed near the path and/or destination of liquid 20. In yet another alternative preferred embodiment, the source of energy beam 50 is an ultrasound gun.

Depending on the precision with which solution 50 must strike substrate 30 and the sensitivity of the components being manufactured to the manufacturing process, the invention may be operated in a normal laboratory atmosphere. However, where such conditions are not satisfactory for the desired purpose, it may be advantageous to alter the conditions. By way of example only, the invention may be operated in a solvent-rich atmosphere or in an inert atmosphere.

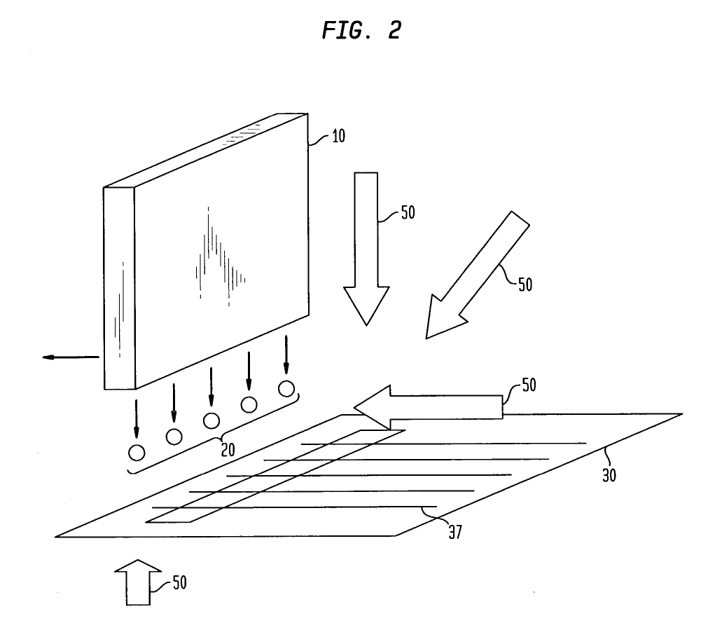

With reference to FIG. 2, another preferred embodiment of the invention is shown, wherein print head 10 has multiple nozzles and substrate 30 does not have confinement walls. Lines 37, which may be lines of pixels if an OLED is being manufactured, are created by liquid drops 20. As with FIG. 1, various possible placements of energy beam 50 are shown. In a preferred embodiment, only a subset of the possible placements of energy beam 50 are utilized.

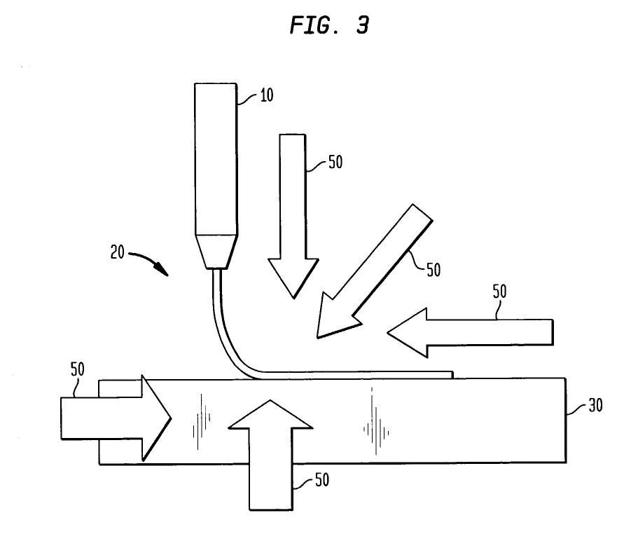

With reference to FIG. 3, another preferred embodiment of the invention is shown, wherein print head 10 is a continuous-stream ink jet dispenser. In this embodiment, liquid 20 is a continuous or semi-continuous stream of liquid.

While the invention has been described in terms of preferred embodiments, those skilled in the art will recognize that the invention can be practiced with modification within the spirit and scope of the appended claims.

We claim:

1. A method for deposing a liquid on a substrate, comprising:
a) emitting said liquid from a print head or nozzle toward said substrate; and
b) modifying at least one component of said liquid, after said emitting, with energy from an energy beam having sufficient intensity to substantially cause said modification.

2. The method for deposing a liquid on a substrate of claim 1, wherein:
said liquid is a solution;
said at least one component is a solvent in said solution;
said modification is at least partial evaporation; and
said solution has at least one solute that is substantially unaffected by said energy beam.

3. The method for deposing a liquid on a substrate of claim 2, wherein other components of said solution remain substantially unaffected by said energy beam.

4. The method for deposing a liquid on a substrate of claim 2, wherein said at least partial evaporation comprises said energy beam directly heating said substrate, and wherein heat is transferred from said substrate to said solution.

5. The method for deposing a liquid on a substrate of claim 1, wherein said energy beam is a laser beam.

6. The method for deposing a liquid on a substrate of claim 1, wherein said at least one component of said liquid before said modification has properties that adversely affect the drying profile of the liquid.

7. The method for deposing a liquid on a substrate of claim 1, wherein said liquid is emitted from said print head or nozzle in the form of drops.

8. The method for deposing a liquid on a substrate of claim 1, wherein said liquid is emitted from said print head or nozzle in the form of a continuous or semi-continuous stream.

9. The method for deposing a liquid on a substrate of claim 1, further comprising:
pulsing said energy beam.

10. The method for deposing a liquid on a substrate of claim 1, further comprising:
moving said energy beam to track said liquid subsequent to when said print head or nozzle emits said liquid.

11. The method for deposing a liquid on a substrate of claim 10, wherein said print head or nozzle and said energy beam are aligned and stationary with respect to each another, and wherein said substrate moves with respect to said print head or nozzle and said energy beam.

12. The method for deposing a liquid on a substrate of claim 1, wherein said at least one component is an additive specifically added to said liquid to interact with said energy beam.

13. The method for deposing a liquid on a substrate of claim 12, wherein said modification is substantial evaporation.

14. The method for deposing a liquid on a substrate of claim 1, wherein said at least one component is an ink.

15. An ink-jet printer comprising:
a print head or nozzle that emits a liquid toward a substrate; and
an energy beam source creating an energy beam having sufficient intensity to substantially cause modification of at least one component of said liquid.

16. The ink-jet printer of claim 15, wherein:
said liquid is a solution;
said at least one component is a solvent in said solution;
said modification is at least partial evaporation; and
said solution has at least one solute that is substantially unaffected by said energy beam.

17. The ink-jet printer of claim 16, wherein other components of said solution remain substantially unaffected by said energy beam.

18. The ink-jet printer of claim 16, wherein said at least partial evaporation comprises said energy beam directly heating said substrate, and wherein heat is transferred from said substrate to said solution.

19. The ink-jet printer of claim 15, wherein said energy beam is a laser beam.

20. The ink-jet printer of claim 15, wherein said energy beam source is positioned to cause said energy beam to heat up said substrate.

21. The ink-jet printer of claim 15, wherein said at least one component in said liquid before said modification has properties that adversely affect the drying profile of the liquid.

22. The ink-jet printer of claim 15, wherein said liquid is in the form of a plurality of drops.

23. The ink-jet printer of claim 16, wherein said liquid is in the form of a continuous or semi-continuous stream.

24. The ink-jet printer of claim 15, wherein said energy beam is a pulsed energy beam.

25. The ink-jet printer of claim 15, wherein said energy beam source is movable to allow said energy beam to track said liquid subsequent to when said print head or nozzle emits said liquid.

26. The ink-jet printer of claim 15, wherein said print head or nozzle and said energy beam are aligned and stationary with respect to each another, and wherein said substrate moves with respect to said print head or nozzle and said energy beam.

27. The ink-jet printer of claim 15, wherein said at least one component is an additive specifically added to said liquid to interact with said energy beam.

28. The ink-jet printer of claim 27, wherein said modification is substantial evaporation.

29. The ink-jet printer of claim 15, wherein said at least one component is an ink.

30. An organic transistor manufactured by a process comprising the steps of:
a) emitting a liquid comprising a solute from a print head or nozzle toward a substrate; and
b) modifying said liquid, after said emitting, with energy from an energy beam having sufficient intensity to substantially cause said modification.

31. An OLED manufactured by a process comprising the steps of:
a) emitting a liquid comprising a solute from a print head or nozzle toward a substrate; and
b) modifying said liquid, after said emitting, with energy from an energy beam having sufficient intensity to substantially cause said modification.
